(19) United States
(12) Patent Application Publication
(10) Pub. No.: US 2008/0258204 A1
(43) Pub. Date: Oct. 23, 2008

(54) MEMORY STRUCTURE AND OPERATING METHOD THEREOF

(75) Inventor: Chao-I Wu, Hsinchu (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 11/737,961

(22) Filed: Apr. 20, 2007

(51) Int. Cl. H01L 29/792; G11C 11/34

(52) U.S. Cl. 257/324; 365/185.29; 257/E29.309

(57) ABSTRACT

A memory structure including a substrate, a charge trapping layer, a block layer, a conducting layer and two doped regions is provided in the present invention. The charge trapping layer is disposed on the substrate. The block layer is disposed on the charge trapping layer. The conducting layer is disposed on the block layer. The doped regions are disposed respectively in the substrate on the two sides of the conducting layer.

### BACKGROUND OF THE INVENTION

1. Field of the Invention

The present invention relates to a memory structure, especially to a random access memory structure of the charge-trapping type and an operating method thereof.

2. Description of Related Art

The development of the communication technology and the popularity of the Internet speed up the growth of people's demands for the exchange and processing of information especially for the transmission of the audio-video data of great capacity and rapid transmission. On the other aspect, faced with global competition, the work environment people are working in nowadays is not limited to the office but anywhere in the world at any time, and a great deal of information is needed to support their action and decision. Hence, portable devices and mobile platforms such as digital notebook computer (NB), personal digital assistant (PDA), e-Book, mobile phone, digital still camera (DSC) and the demands for them have significantly grown. As a result, the demands for the storage devices to access the aforementioned digital products also increase in significant proportion correspondingly.

The memory developed from the semiconductor storage technology since 1990 has now become a burgeoning technology of the storage medium. In order to satisfy the demands for memories which expand as the demands for storage or transmission of large capacity of data, developing new types of memory elements has much significance and value.

### SUMMARY OF THE INVENTION

In view of this, the present invention provides a memory structure that effectively reduces the volume of memory cells and the complexity in the fabrication process.

The invention further provides a three-dimensional memory structure, which significantly upgrades the integrity of the memory element.

The invention further provides an operating method of a memory structure with faster programming and erasing speeds.

The invention further provides an operating method of a memory structure with a longer data retention time so that the power consumption is lowered.

A memory structure including a substrate, a charge trapping layer, a block layer, a conducting layer and two doped regions is provided in the invention. The charge trapping layer is disposed on the substrate. The block layer is disposed on the charge trapping layer. The conducting layer is disposed on the block layer. The doped regions are disposed respectively in the substrate on the two sides of the conducting layer.

According to one embodiment of the invention, in the memory structure, the substrate includes a silicon substrate.

According to one embodiment of the invention, in the memory structure, the silicon substrate includes a monocrystalline silicon substrate or a polycrystalline substrate.

According to one embodiment of the invention, in the memory structure, the material of the charge trapping layer includes high dielectric constant trapping materials.

According to one embodiment of the invention, in the memory structure, the material of the charge trapping layer includes silicon nitride, aluminum oxide or hafnium oxide.

According to one embodiment of the invention, in the memory structure, the material of the block layer includes high dielectric constant blocking materials.

According to one embodiment of the invention, in the memory structure, the material of the block layer includes silicon oxide, silicon nitride, aluminum oxide or hafnium oxide.

According to one embodiment of the invention, in the memory structure, the material of the conducting layer includes doped polycrystalline silicon or metals.

According to one embodiment of the invention, in the memory structure, the memory structure is a dynamic random access memory (DRAM) or a static random access memory (SRAM).

The invention provides a three-dimensional memory structure including a substrate, a first isolation layer and a first memory structure. The first isolation layer is disposed on the substrate. The first memory structure includes a polycrystalline silicon substrate, a charge trapping layer, a block layer, a conducting layer and two doped regions. The polycrystalline silicon substrate is disposed on the first isolation layer. The charge trapping layer is disposed on the polycrystalline silicon substrate. The block layer is disposed on the charge trapping layer. The conducting layer is disposed on the block layer. The doped regions are disposed respectively in the polycrystalline silicon substrate on the two sides of the conducting layer.

According to one embodiment of the invention, the three-dimensional memory structure further includes a second isolation layer and a second memory structure.

The second isolation layer is disposed on the first memory structure. The second memory structure is disposed on the second isolation layer and has the same structure as the first memory structure.

According to one embodiment of the invention, in the three-dimensional memory structure, the material of the second isolation layer includes silicon oxide.

According to one embodiment of the invention, in the three-dimensional memory structure, the second memory structure is a DRAM or an SRAM.

According to one embodiment of the invention, in the three-dimensional memory structure, the substrate includes a silicon substrate.

According to one embodiment of the invention, in the three-dimensional memory structure, the substrate has a semiconductor element thereon.

According to one embodiment of the invention, in the three-dimensional memory structure, the semiconductor element includes a memory or a metal-oxide-semiconductor (MOS) transistor.

According to one embodiment of the invention, in the three-dimensional memory structure, the material of the charge trapping layer includes high dielectric constant trapping materials.

According to one embodiment of the invention, in the three-dimensional memory structure, the material of the charge trapping layer includes silicon nitride, aluminum oxide or hafnium oxide.

According to one embodiment of the invention, in the three-dimensional memory structure, the material of the block layer includes high dielectric constant blocking materials.

According to one embodiment of the invention, in the three-dimensional memory structure, the material of the block layer includes silicon oxide, silicon nitride, aluminum oxide or hafnium oxide.

According to one embodiment of the invention, in the three-dimensional memory structure, the material of the conducting layer includes doped polycrystalline silicon or metals.

According to one embodiment of the invention, in the three-dimensional memory structure, the material of the first isolation layer includes silicon oxide.

According to one embodiment of the invention, in the three-dimensional memory structure, the first memory structure is a DRAM or an SRAM.

The present invention provides an operating method of a memory structure. The memory structure includes a substrate, a charge trapping layer, a block layer, a conducting layer and two doped regions. The charge trapping layer is disposed on the substrate. The block layer is disposed on the charge trapping layer. The conducting layer is disposed on the block layer and the doped regions are disposed respectively in the substrate on the two sides of the conducting layer. The operating method includes first applying a first voltage on the conducting layer. Next, a second voltage is applied on the substrate. The voltage difference between the first voltage and the second voltage is sufficient to trigger the Fowler-Nordheim tunneling effect so as to induce charges into the charge trapping layer or release charges from the charge trapping layer.

According to one embodiment of the invention, in the operating method of the memory structure, the first voltage is 8 volts to 20 volts, and the second voltage is 0 volt.

According to one embodiment of the invention, in the operating method of the memory structure, the first voltage is −8 volts to −20 volts, and the second voltage is 0 volt.

According to one embodiment of the invention, in the operating method of the memory structure, injecting charges into the charge trapping layer is the programming operation and releasing charges from the charge trapping layer is the erasing operation.

The present invention provides another operating method of a memory structure. The memory structure includes a substrate, a charge trapping layer, a block layer, a conducting layer and two doped regions. The charge trapping layer is disposed on the substrate. The block layer is disposed on the charge trapping layer. The conducting layer is disposed on the block layer and the doped regions are disposed respectively in the substrate on the two sides of the conducting layer. The operating method includes that the first programming operation is first performed on the memory structure so as to induce charges into the charge trapping layer. Next, when the charges in the charge trapping layer are lost, a refreshing operation is performed on the memory structure.

According to another embodiment of the invention, in the operating method of the memory structure, the refreshing operation includes that an erasing operation is first performed on the memory structure. Afterwards, the second programming operation is performed on the memory structure.

According to another embodiment of the invention, in the operating method of the memory structure, after the erasing operation, the refreshing operation further includes that a third checking step is performed to verify whether the erasing operation is completed. When the result of the third checking step confirms the completion of the erasing operation, the second programming operation is performed. When the result of the third checking step indicates the erasing operation as incomplete, the erasing operation is continued.

According to another embodiment of the invention, in the operating method of the memory structure, the refreshing operation includes that the second programming operation is performed on the memory structure.

According to another embodiment of the invention, the operating method of the memory structure, after performing the first programming operation, further includes that the first checking step is performed on the memory structure to verify whether the first programming operation is complete. When the result of the first checking step confirms the completion of the first programming operation, the first programming operation is finished. When the result of the first checking step indicates the first programming operation as incomplete, the first programming operation is continued.

According to another embodiment of the invention, the operating method of the memory structure, after finishing the first programming operation, further includes that the second checking step is performed on the memory structure to verify whether the charges in the charge trapping layer are lost. When the result of the second checking step confirms that the charges in the charge trapping layer are already lost, a refreshing operation is performed. When the result of the second checking step indicates that the charges in the charge trapping layer are not lost, the second checking step is continued.

Based on the foregoing, since the memory structure provided in the invention has an MOS-like structure and does not need a capacitor, the volume of memory cells, the complexity in the fabrication process and the production costs are thus reduced.

On the other aspect, the charges are stored in the charge trapping layer of the memory structure, and thus they have a longer data retention time. As a result, the number of refreshing operations is reduced and the power consumption is lowered.

In addition, the three-dimensional memory structure provided in the invention may be formed on a substrate that has other semiconductor elements such that the integrity of a memory is effectively upgraded.

Moreover, the operating method of the memory structure provided in the invention has faster programming and erasing speeds because there is no film or layer between the charge trapping layer and the substrate of the memory structure.

Besides, the operating method of the memory structure provided in the invention includes refreshing operations so as to prevent loss of the data. If checking steps are added into the operations performed on the memory structure, the timing for performing programming and erasing operations can be accurately controlled.

In order to the make the aforementioned and other objects, features and advantages of the present invention more comprehensible, preferred embodiments accompanied with figures are described in detail below.

### BRIEF DESCRIPTION OF THE DRAWINGS

FIG. 1 is a schematic cross-sectional view of a memory structure according to one embodiment of the present invention.

FIG. 2 is a schematic cross-sectional view of a three-dimensional DRAM structure according to one embodiment of the invention.

FIG. 3 is a flowchart of an operating method of a memory structure according to one embodiment of the invention.

FIG. 4 is a flowchart of the refreshing operation on the DRAM structure according to the first embodiment of the invention.

FIG. 5 is a flowchart of the refreshing operation on the DRAM structure according to the second embodiment of the invention.

FIG. 6 is a flowchart of the refreshing operation on the DRAM structure according to the third embodiment of the invention.

FIG. 7 is a flowchart of the refreshing operation on the DRAM structure according to the fourth embodiment of the invention.

### DESCRIPTION OF EMBODIMENTS

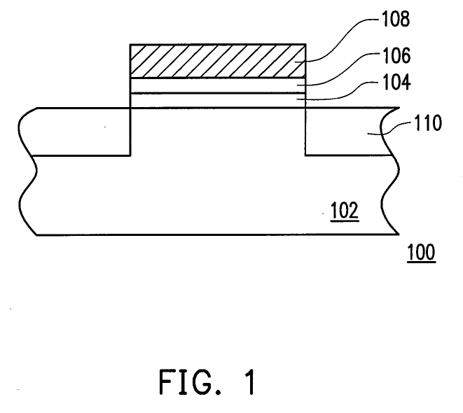

FIG. 1 is a schematic cross-sectional view of a memory structure according to one embodiment of the present invention.

Referring to FIG. 1, a memory structure 100 includes a substrate 102, a charge trapping layer 104, a block layer 106, a conducting layer 108 and doped regions 110. The substrate 102 may be a silicon substrate such as a monocrystalline silicon substrate or a polycrystalline silicon substrate. Furthermore, people ordinarily skilled in the art may dope the substrate 102 depending on designs of the memory.

The charge trapping layer 140 is disposed on the substrate 102 for trapping charges inside and may have the characteristic of a low barrier height. The material of the charge trapping layer 104 may be silicon nitride, aluminum oxide, hafnium oxide or other high dielectric constant trapping materials. The high dielectric constant is defined herein as a dielectric constant higher than that of silicon oxide (around 3.9). The forming method of the charge trapping layer 104 may be a chemical vapor deposition (CVD) process. The block layer 106 is disposed on the charge trapping layer 104 for blocking the passage of charges. The block layer 106 may be silicon oxide, silicon nitride, aluminum oxide, hafnium oxide or other high dielectric constant blocking materials. The forming method of the block layer 106 may be a CVD process.

The conducting layer 108 is disposed on the block layer 106 to be used as a gate. The material of the conducting layer 108 may be doped polycrystalline silicon or metals. The forming method of the conducting layer 108 may be a CVD process or a physical vapor deposition (PVD) process depending on its material(s).

The doped regions 110 are disposed in the substrate 102 on the two sides of the conducting layer 108 to be used as a source/drain. The doped region 110 may be formed by an ion implantation process. The dopant of the doped regions 110 may be N-type dopants like phosphorous or P-type dopants like boron. People ordinarily skilled in the art may adjust the dopant according to designs of the memory. Generally speaking, the doped regions 110 and the substrate 102 are of two different dope types.

Since there is no film or layer between the charge trapping layer 104 and the substrate 102 in the memory structure 100, the programming operation and the erasing operation perform rather rapidly within 30 nano-seconds (ns). However, the charges stored in the charge trapping layer 104 are gradually lost and need refreshing operations to prevent further loss. Thus, the memory structure 100 is rendered as having the characteristic of a random access memory and can be applied in the DRAM or the SRAM. Moreover, the memory structure 100 stores charges in the charge trapping layer 104 thereof and belongs to the charge-trapping type memory. Hence, the data retentions time is longer, the number of refreshing operations is reduced, and the power consumption is thus lowered.

According to the aforementioned, the memory structure 100 of the invention when applied in the DRAM is called a trapping DRAM (TDRAM), and when applied in the SDRM is called a trapping SRAM (TSRAM).

It is known from the foregoing embodiments that the structure of the memory structure 100 is relatively simple and similar to the MOS transistor. When the memory structure 100 is a TDRAM, compared to the conventional DRAM structure, the memory structure 100 does not need a capacitor and thus reduces the volume of memory cells, the complexity in the fabrication process and the production costs.

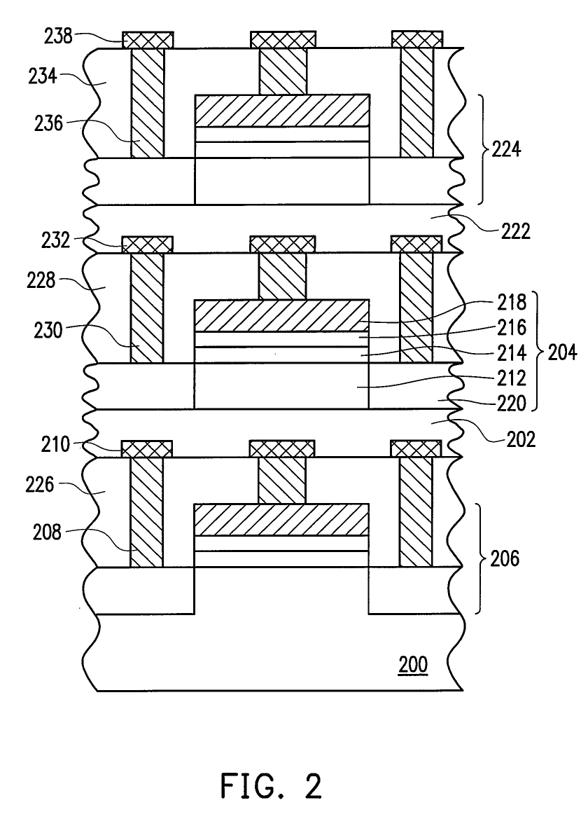

FIG. 2 is a schematic cross-sectional view of a three-dimensional DRAM structure according to one embodiment of the invention.

Referring to both FIGS. 1 and 2, a three-dimensional memory structure includes a substrate 200, a first isolation layer 202 and a first memory structure 204. The substrate 200 may be a monocrystalline silicon substrate. A dielectric layer 226 on the substrate 200 has a semiconductor element 206. The semiconductor element 206 may be a memory like a DRAM, an SRAM or a TDRAM, or a metal oxide semiconductor like a CMOS, an NMOS or a CMOS.

In the present embodiment, the semiconductor element 206 shown in FIG. 2 may be a TDRAM with the same structure as the memory structure 100 of FIG. 1. Operations performed on the semiconductor element 206 may proceed through a contact 208 in the dielectric layer 226 and a conductive line 210 on the dielectric layer 226.

The first isolation layer 202 is disposed on the substrate 200 to isolate the two adjacent upper and lower semiconductor elements. The material of the first isolation layer 202 may be silicon oxide. The method of forming the first isolation layer 202 may be a CVD process.

A first memory structure 204 is disposed on the first isolation layer 202 and includes a polycrystalline silicon substrate 212, a charge trapping layer 214, a block layer 216, a conducting layer 218 and doped regions 220. Operations performed on the first memory structure 204 may proceed through a contact 230 in a dielectric 228 and a conductive line 232 on the dielectric layer 228. The first memory structure 204 may be a TDRAM or a TSRAM.

The polycrystalline silicon substrate 212 is disposed on the first isolation layer 202. The method of forming the polycrystalline silicon substrate 212 may be a CVD process. Furthermore, people ordinarily skilled in the art may dope the polycrystalline silicon substrate 212 according to designs of the memory. In the first memory structure 204, except that the substrate thereof is designated as the polycrystalline silicon substrate 212, the rest of the elements are all similar to the elements of the memory structure 100 of FIG. 1 and therefore are not to be reiterated herein.

In addition, the three-dimensional memory structure further includes a second isolation layer 222 and a second memory structure 224. The second isolation layer 222 is disposed on the first memory structure 204 to isolate the two adjacent upper and lower semiconductor elements. The material of the second isolation layer 222 may be silicon oxide. The method of forming the second isolation layer 222 may be a CVD process.

The second memory structure 224 is disposed on the second isolation layer 222 and has the same structure as the first memory structure 204 with a polycrystalline silicon substrate as the substrate. Operations performed on the second memory structure 224 may proceed through a contact 236 in a dielectric layer 234 and a conductive line 238 on the dielectric layer 234. The second memory structure 224 may be a TDRAM or a TSRAM.

It is known from the foregoing embodiments that the three-dimensional memory structure stacks memory structures applying polycrystalline silicon substrates as the substrates (such as the first memory structure 204 and the second memory structure 224) on the substrate 200. The three-dimensional memory structure uses the first isolation layer 202 and the second isolation layer 222 to isolate the two adjacent semiconductor elements so as to form the three-dimensional memory structure and effectively upgrade the integrity of the memory.

Although the present embodiment illustrates by stacking two memory structures applying polycrystalline silicon substrates as the substrates (like the first memory structure 204 and the second DRAM structure 224) on the substrate 200, people ordinarily skilled in the art may adjust the number of stacked memory structures applying polycrystalline silicon substrates as the substrates according to their needs.

The following takes the memory structure 100 of FIG. 1 as an example to introduce the operating method of the memory structure of the invention.

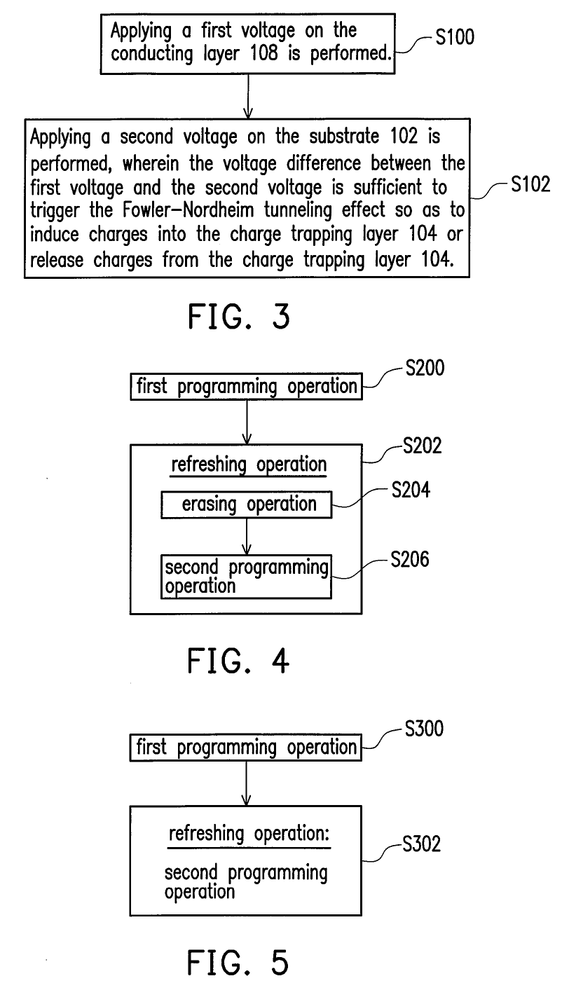

FIG. 3 is a flowchart of an operating method of a memory structure according to one embodiment of the invention.

Referring to FIGS. 1 and 3, first, step S100 is performed applying a first voltage on the conducting layer 108. Next, step S102 is performed applying a second voltage on the substrate 102, wherein the voltage difference between the first voltage and the second voltage is sufficient to trigger the Fowler-Nordheim tunneling effect so as to induce charges into the charge trapping layer 104 or release charges from the charge trapping layer 104. A charge may be an electron or a hole.

Injecting electrons into the charge trapping layer 104 is defined herein as a programming operation and releasing electrons from the charge trapping layer 104 is defined as an erasing operation so as to facilitate the illustration of the present embodiment. However, the said definitions of the programming operation and the erasing operation are not intended to limit the invention. People ordinarily skilled in the art may set the definitions to suit their own needs.

In view of the aforementioned, when the programming operation is performed on the memory structure 100, the first voltage applied on the conducting layer 108 may be 8 volts to 20 volts and the second voltage applied on the substrate 102 may be 0 volt so that the F—N tunneling effect is triggered and electrons are induced into the charge trapping layer 104. On the other aspect, when the erasing operation is performed on the memory structure 100, the first voltage applied on the conducting layer 108 may be −8 volts to −20 volts and the second voltage applied on the substrate 102 may be 0 volt so that the F—N tunneling effect is triggered and electrons are released from the charge trapping layer 104.

Since there is no film or layer between the charge trapping layer 104 and the substrate 102 in the memory structure 100, the programming operation and the erasing operation proceed rather rapidly within 30 nano-seconds (ns).

Nevertheless, the charges stored in the charge trapping layer of the memory structure provided by the invention are gradually lost. Hence, when operations are performed on the memory structure, the memory structure has to be constantly recharged for a refreshing operation of the data to proceed. The operating method of the refreshing operation performed on the memory structure of the invention is introduced in the following.

FIG. 4 is a flowchart of the refreshing operation on the memory structure according to the first embodiment of the invention.

Referring to FIG. 4, first, step S200 is executed, performing a first programming operation on the memory structure to induce charges into the charge trapping layer. The memory structure being operated upon may be the memory structure 100 of FIG. 1.

Afterwards, step S202 is executed. When the charges in the charge trapping layer are lost, a refreshing operation is performed on the memory structure. The refreshing operation includes that firstly step S204 is executed performing the erasing operation on the memory structure. Afterwards, step S206 is executed, performing a second programming operation on the memory structure.

FIG. 5 is a flowchart of the refreshing operation on the memory structure according to the second embodiment of the invention.

Referring to FIG. 5, first, step S300 is executed, performing a first programming operation on the memory structure to induce charges into the charge trapping layer. The DRAM structure being operated upon is the memory structure 100 of FIG. 1.

Afterwards, step S302 is executed. When the charges in the charge trapping layer are lost, the refreshing operation is performed on the memory structure. The refreshing operation performed may be the second programming operation.

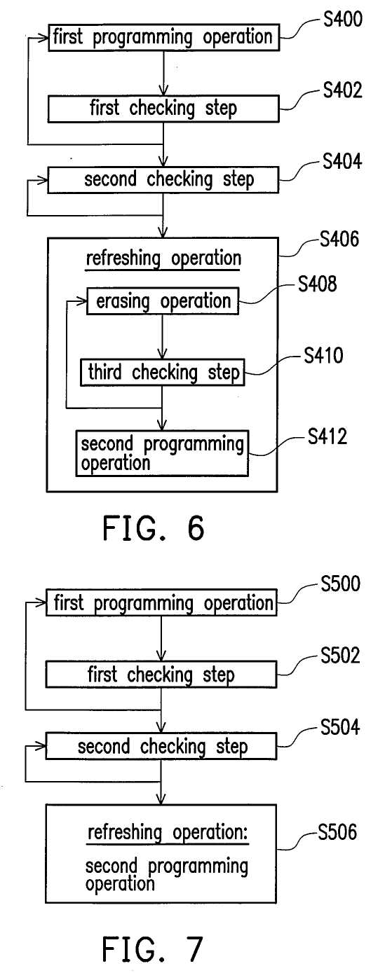

FIG. 6 is a flowchart of the refreshing operation on the memory structure according to the third embodiment of the invention.

Referring to FIG. 6, first, step S400 is executed, performing a first programming operation on the memory structure to induce charges into the charge trapping layer. The memory structure being operated upon is the memory structure 100 of FIG. 1.

Afterwards, step S402 may be optionally executed, performing a first checking step on the memory structure to verify whether the first programming operation is completed. When the result of the first checking step confirms the completion of the first programming operation, the first programming operation is finished. When the results indicate the first programming operation as incomplete, the process reverts to the step S400 to proceed with the first programming operation.

Then, after finishing the first programming operation, step S404 may be optionally executed, performing a second checking step on the memory structure to verify whether the charges in the charge trapping layer are lost. When the result of the second checking step confirms the charges in the charge trapping layer are already lost, step S406 is executed performing a refreshing operation. When the result of the second checking step indicates the charges in the charge trapping layer as not lost, the process reverts to the step S404 to proceed with the second checking step.

Afterwards, step S406 is executed. When the charges in the charge trapping layer are lost, the refreshing operation is performed on the memory structure. The refreshing operation includes that firstly step S408 is executed performing the erasing operation on the memory structure.

Next, step S410 may be optionally executed performing a third checking step on the memory structure so as to verify whether the erasing operation is completed. When the result of the third checking step confirms the erasing operation is completed, the process proceeds to step S412 performing a second programming operation. When the result of the third checking step indicates the erasing operation as incomplete, the process reverts to the step S408 to proceed with the erasing operation.

Then, the step S412 is executed, performing the second programming operation on the memory structure.

FIG. 7 is a flowchart of the refreshing operation on the memory structure according to the fourth embodiment of the invention.

Referring to FIG. 7, first, step S500 is executed, performing a first programming operation on the memory structure to induce charges into the charge trapping layer. The memory structure being operated upon is the memory structure 100 of FIG. 1.

Afterwards, step S502 may be optionally executed, performing a first checking step on the memory structure to verify whether the first programming operation is completed. When the result of the first checking step confirms the completion of the first programming operation, the first programming operation is finished. When the result indicates the first programming operation as incomplete, the process reverts to the step S500 to proceed with the first programming operation.

Then, after the first programming operation is finished, step S504 may be optionally executed performing a second checking step on the memory structure so as to verify whether the charges in the charge trapping layer are lost. When the result of the second checking step confirms the charges in the charge trapping layer are already lost, the process proceeds to step S506 performing a refreshing operation. When the result of the second checking step indicates the charges in the charge trapping layer as not lost, the process reverts to the step S504 to proceed with the second checking step.

Afterwards, step S506 is executed. When the charges in the charge trapping layer are lost, the refreshing operation is performed on the memory structure. The refreshing operation performed may be the second programming operation.

It is noted the embodiments illustrated in FIGS. 4 and 5 are the basic implementation types for the refreshing operation on the memory structure of the present invention. The embodiments illustrated on FIGS. 6 and 7 respectively add checking steps to the embodiments of FIGS. 4 and 5 and all the checking steps may be executed optionally. In other words, those ordinarily skilled in the art may add necessary checking steps into the basic implementation types illustrated in FIGS. 4 and 5 according to actual needs. Therefore, the refreshing operation performed on the memory structure of the invention is not limited to those illustrated in the embodiments of FIGS. 4 to 7.

According to the aforementioned, since the operating method of the memory structure disclosed by the invention includes the refreshing operation, avoiding loss of the data from the charge trapping layer can thus be effectively achieved. Additionally, when the memory structure is being operated upon, adding checking steps ensures accurate control of the timing for the programming operation and the erasing operation.

In summary, the present invention has at least the following advantages:

1. The memory structure provided by the present invention reduces the volume of memory cells, the complexity in the fabrication process and the production costs.

2. The memory structure provided by the invention has a longer data retention time. Therefore, the number of refreshing operations is reduced and the overall power consumption is lowered.

3. The three-dimensional memory structure provided by the invention effectively upgrades the integrity of the memory.

4. The operating method provided by the invention performs the programming operation and the erasing operation at faster speeds.

5. The operating method provided by the invention includes the refreshing operation, and thus prevents loss of the data.

6. The operating method provided by the invention accurately controls the timing for the programming operation and the erasing operation.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A memory structure, comprising:
a substrate;
a charge trapping layer, disposed on the substrate;
a block layer, disposed on the charge trapping layer;
a conducting layer, disposed on the block layer, and
two doped regions, respectively disposed in the substrate on the two sides of the conducting layer.

2. The memory structure as claimed in claim 1, wherein the substrate comprises a silicon substrate.

3. The memory structure of claim 1, wherein the silicon substrate comprises a monocrystalline silicon substrate or a polycrystalline silicon substrate.

4. The memory structure as claimed in claim 1, wherein the material of the charge trapping layer comprises high dielectric constant trapping materials.

5. The memory structure as claimed in claim 1, wherein the material of the charge trapping layer comprises silicon nitride, aluminum oxide or hafnium oxide.

6. The memory structure as claimed in claim 1, wherein the material of the block layer comprises high dielectric constant blocking materials.

7. The memory structure as claimed in claim 1, wherein the material of the block layer comprises silicon oxide, silicon nitride, aluminum oxide or hafnium oxide.

8. The memory structure as claimed in claim 1, wherein the material of the conducting layer comprises doped polycrystalline silicon or metals.

9. The memory structure as claimed in claim 1, wherein the memory structure is a dynamic random access memory (DRAM) or a static random access memory (SRAM).

10. A three-dimensional memory structure, comprising:
a substrate;
a first isolation layer, disposed on the substrate; and
a first memory structure, comprising:
a polycrystalline silicon substrate, disposed on the first isolation layer;
a charge trapping layer, disposed on the polycrystalline silicon substrate;
a block layer, disposed on the charge trapping layer;
a conducting layer, disposed on the block layer; and
two doped regions, respectively disposed in the polycrystalline silicon substrate on the two sides of the conducting layer.

11. The three-dimensional memory structure as claimed in claim 10, further comprising:
a second isolation layer, disposed on the first memory structure; and
a second memory structure, disposed on the second isolation layer and having the same structure as the first memory structure.

12. The three-dimensional memory structure as claimed in claim 11, wherein the material of the second isolation layer comprises silicon oxide.

13. The three-dimensional memory structure as claimed in claim 11, wherein the second memory structure is a DRAM or an SRAM.

14. The three-dimensional memory structure as claimed in claim 10, wherein the substrate comprises a silicon substrate.

15. The three-dimensional memory structure as claimed in claim 10, wherein the substrate has a semiconductor element thereon.

16. The three-dimensional memory structure as claimed in claim 15, wherein the semiconductor element comprises a memory or a metal oxide semiconductor (MOS) transistor.

17. The three-dimensional memory structure as claimed in claim 10, wherein the material of the charge trapping layer comprises high dielectric constant trapping materials.

18. The three-dimensional memory structure as claimed in claim 10, wherein the material of the charge trapping layer comprises silicon nitride, aluminum oxide or hafnium oxide.

19. The three-dimensional memory structure as claimed in claim 10, wherein the material of the block layer comprises high dielectric constant blocking materials.

20. The three-dimensional memory structure as claimed in claim 10, wherein the material of the block layer comprises silicon oxide, silicon nitride, aluminum oxide or hafnium oxide.

21. The three-dimensional memory structure as claimed in claim 10, wherein the material of the conducting layer comprises doped polycrystalline silicon or metals.

22. The three-dimensional memory structure as claimed in claim 10, wherein the material of the first isolation layer comprises silicon oxide.

23. The three-dimensional memory structure as claimed in claim 10, wherein the first memory structure is a DRAM or an SRAM.

24. An operating method of a memory structure, wherein the memory structure includes a substrate, a charge trapping layer, a block layer, a conducting layer and two doped regions, the charge trapping layer disposed on the substrate, the block layer disposed on the charge trapping layer, the conducting layer disposed on the block layer, the doped regions disposed respectively in the substrate on the two sides of the conducting layer, the operating method comprising:
applying a first voltage on the conducing layer; and
applying a second voltage on the substrate, wherein
the voltage difference between the first voltage and the second voltage is sufficient to trigger the Fowler-Nordheim tunneling effect so as to induce charges into the charge trapping layer or release charges from the charge trapping layer.

25. The operating method of the memory structure as claimed in claim 24, wherein the first voltage is 8 volts to 20 volts, the second voltage being 0 volt.

26. The operating method of the memory structure as claimed in claim 24, wherein the first voltage is −8 volts to −20 volts, the second voltage being 0 volt.

27. The operating method of the memory structure as claimed in claim 24, wherein injecting charges into the charge trapping layer is a programming operation, releasing charges from the charge trapping layer being an erasing operation.

28. An operating method of a memory structure, wherein the memory structure includes a substrate, a charge trapping layer, a block layer, a conducting layer and two doped regions, the charge trapping layer disposed on the substrate, the block layer disposed on the charge trapping layer, the conducting layer disposed on the block layer, the doped regions disposed respectively in the substrate on the two sides of the conducting layer, the operating method comprising:
performing a first programming operation on the memory structure to induce charges into the charge trapping layer; and
when the charges in the charge trapping layer being lost, performing a refreshing operation on the memory structure.

29. The operating method of the memory structure as claimed in claim 28, wherein the refreshing operation comprises:
performing an erasing operation on the memory structure; and
performing a second programming operation on the memory structure.

30. The operating method of the memory structure as claimed in claim 29, wherein after executing the erasing operation, the refreshing operation further comprises performing a third checking step on the memory structure to verify whether the erasing operation is completed,
when the result of the third checking step confirming the completion of the erasing operation, performing the second programming operation,
when the result of the third checking step indicating the erasing operation as incomplete, continuing the erasing operation.

31. The operating method of the memory structure as claimed in claim 28, wherein the refreshing operation comprises performing the second programming operation on the memory structure.

32. The operating method of the memory structure as claimed in claim 28, after executing the first programming operation, further comprising performing the first checking step on the memory structure to verify whether the first programming operation is completed,
when the result of the first checking step confirming the completion of the first programming operation, finishing the first programming operation,
when the result of the first checking step indicating the first programming operation as incomplete, continuing the first programming operation.

33. The operating method of the memory structure as claimed in claim 32, after finishing the first programming operation, further comprising performing a second checking step on the memory structure to verify whether the charges in the charge trapping layer are lost,
when the result of the second checking step confirming the charges in the charge trapping layer already lost, performing the refreshing operation,
when the result of the second checking step indicating the charges in the charge trapping layer as not lost, continuing the second checking step.

34. The operating method of the memory structure as claimed in claim 33, wherein the refreshing operation comprises:
performing an erasing operation on the memory structure; and
performing a second programming operation on the memory structure.

35. The operating method of the memory structure as claimed in claim 34, wherein after executing the erasing operation, the refreshing operation further comprises performing a third checking step on the memory structure to verify whether the erasing operation is completed,
when the result of the third checking step confirming the completion of the erasing operation, performing the second programming operation,
when the result of the third checking step indicating the erasing operation as incomplete, continuing the erasing operation.

36. The operating method of the memory structure as claimed in claim 33, wherein the refreshing operation comprises performing a second programming operation on the memory structure.

37. The operating method of the memory structure as claimed in claim 32, wherein the refreshing operation comprises:
performing an erasing operation on the memory structure; and
performing a second programming operation on the memory structure.

38. The operating method of the memory structure as claimed in claim 37, wherein after executing the erasing operation, the refreshing operation further comprises performing a third checking step on the memory structure to verify whether the erasing operation is completed,
when the result of the third checking step confirming the completion of the erasing operation, performing the second programming operation,
when the result of the third checking step indicating the erasing operation as incomplete, continuing the erasing operation.

39. The operating method of the memory structure as claimed in claim 32, wherein the refreshing operation comprises performing a second programming operation on the memory structure.

40. The operating method of the memory structure as claimed in claim 28, after finishing the first programming operation, further comprising performing a second checking step on the memory structure to verify whether the charges in the charge trapping layer are lost,
when the result of the second checking step confirming the charges in the charge trapping layer already lost, performing the refreshing operation,
when the result of the second checking step indicating the charges in the charge trapping layer as not lost, continuing the second checking step.

41. The operating method of the memory structure as claimed in claim 40, wherein the refreshing operation comprises:
performing an erasing operation on the memory structure; and
performing a second programming operation on the memory structure.

42. The operating method of the memory structure as claimed in claim 41, wherein after executing the erasing operation, the refreshing operation further comprises performing a third checking step on the memory structure to verify whether the erasing operation is completed,
when the result of the third checking step confirming the completion of the erasing operation, performing the second programming operation,
when the result of the third checking step indicating the erasing operation as incomplete, continuing the erasing operation.

43. The operating method of the memory structure as claimed in claim 40, wherein the refreshing operation comprises performing a second programming operation on the memory structure.
